(19) United States
(12) Patent Application Publication
(10) Pub. No.: US 2025/0160145 A1
(43) Pub. Date: May 15, 2025

(54) DISPLAY DEVICE AND METHOD OF FABRICATING THE SAME

(71) Applicant: Samsung Display Co., LTD., Yongin-si (KR)

(72) Inventors: Chang Ho YI, Yongin-si (KR); Joo Sun YOON, Yongin-si (KR)

(73) Assignee: Samsung Display Co., LTD., Yongin-si (KR)

(21) Appl. No.: 18/763,636

(22) Filed: Jul. 3, 2024

(30) Foreign Application Priority Data
Nov. 14, 2023 (KR) 10-2023-0157086

(51) Int. Cl. H10K 59/131; H10K 59/12; H10K 59/122; H10K 71/60

(52) U.S. Cl. CPC H10K 59/131; H10K 59/1201; H10K 59/122; H10K 71/60

(57) ABSTRACT

A display device includes, a voltage line including a first metal layer and a first transparent conductive layer on the first metal layer, an insulating layer on the voltage line including a first hole exposing a part of the first transparent conductive layer, a pad electrode on the insulating layer including a second transparent conductive layer contacting the first transparent conductive layer where the first hole is disposed, a pixel-defining layer on the pad electrode including a second hole exposing a part of the pad electrode, and a common electrode on the pixel-defining layer contacting the pad electrode where the second hole is disposed. The first transparent conductive layer has a smaller width than the first metal layer, and an end of the first transparent conductive layer is spaced apart from an end of the first metal layer by a first distance at an end of the voltage line.

### CROSS-REFERENCE TO RELATED APPLICATION(S)

This application claims priority to and benefits of Korean Patent Application No. 10-2023-0157086 under 35 U.S.C. § 119 filed on Nov. 14, 2023, in the Korean Intellectual Property Office, the entire contents of which are incorporated herein by reference.

### BACKGROUND

### 1. Technical Field

Embodiments relate to a display device, and a method of fabricating the same.

### 2. Description of the Related Art

Display devices become more and more important as multimedia technology evolves. In accordance with this, a variety of display devices, including a light-emitting display device, are being developed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects provide a display device that can prevent or reduce voltage drop in a pixel voltage, and a method of fabricating a display device.

However, aspects are not restricted to the ones set forth herein. The above and other aspects will become more apparent to one of ordinary skill in the art to which the disclosure pertains by referencing the detailed description of the disclosure given below.

According to an aspect, there is provided a display device including, a voltage line disposed in a display area on a substrate the voltage line including a first metal layer and a first transparent conductive layer on the first metal layer; an insulating layer disposed on the voltage line, the insulating layer including a first hole exposing a part of the first transparent conductive layer; a pad electrode disposed on the insulating layer, the pad electrode including a second transparent conductive layer contacting the first transparent conductive layer where the first hole is disposed; a pixel-defining layer disposed on the pad electrode the pixel-defining layer including a second hole exposing a part of the pad electrode; and a common electrode disposed on the pixel-defining layer, the common electrode contacting the pad electrode where the second hole is disposed. The first transparent conductive layer may have a smaller width than a width of the first metal layer, and an end of the first transparent conductive layer is spaced apart from an end of the first metal layer by a first distance at an end of the voltage line.

In an embodiment, the first distance may be equal to or greater than about 0.1 μm.

In an embodiment, the first distance may be in a range of about 0.1 μm to about 0.2 μm.

In an embodiment, the first transparent conductive layer and the second transparent conductive layer may include one or more same elements.

In an embodiment, the first transparent conductive layer and the second transparent conductive layer may include a transparent conductive oxide including indium (In).

In an embodiment, the first transparent conductive layer may be made of indium-tin oxide (ITO), indium-zinc oxide (IZO), or indium-gallium-zinc oxide (IGZO), and the second transparent conductive layer may be made of indium-tin oxide (ITO).

In an embodiment, the first metal layer may protrude from both sides of the first transparent conductive layer in a width direction of the voltage line.

In an embodiment, the first metal layer may have a multi-layer structure including a first layer including a first metal, a second layer disposed on the first layer and including a second metal, and a third layer disposed on the second layer and including a third metal.

In an embodiment, the first metal and the third metal are titanium (Ti), and the second metal may be aluminum (Al).

In an embodiment, the pad electrode may further include a second metal layer disposed on the second transparent conductive layer, and a third transparent conductive layer disposed on the second metal layer.

In an embodiment, the second transparent conductive layer and the third transparent conductive layer may include indium-tin oxide (ITO), and the second metal layer may include silver (Ag).

In an embodiment, the display device may further include, a panel circuit layer disposed on the substrate, the panel circuit layer including a transistor disposed in the display area and the voltage line; a light-emitting element layer disposed in the display area on the panel circuit layer and including a pixel electrode disposed in a same layer as the pad electrode and spaced apart from the pad electrode; an emissive layer disposed between the pixel electrode and the common electrode, the common electrode, and the pixel-defining layer, and an encapsulation layer disposed on the light-emitting element layer.

In an embodiment, the pixel-defining layer may be opened in an emission area where the pixel electrode and the emissive layer overlap each other to expose the pixel electrode.

In an embodiment, the display area may further include a non-emission area around the emission area, the common electrode may be disposed entirely in the display area, and the pad electrode and the second hole may be disposed in the non-emission area.

In an embodiment, the display device may further include at least one common layer disposed between the pixel-defining layer and the common electrode and overlapping the pad electrode, and the second hole may penetrate the pixel-defining layer and the at least one common layer.

According to an aspect, there is provided a method of fabricating a display device, the method including, forming a multi-layer conductive film by sequentially forming a first metal layer and a first transparent conductive layer on a substrate; disposing a mask on a portion of the conductive film; forming a voltage line by sequentially etching the first transparent conductive layer and the first metal layer using the mask; forming an insulating layer on the voltage line and forming a first hole in the insulating layer to expose a portion of the first transparent conductive layer; forming a pad electrode on the insulating layer, the pad electrode overlapping the voltage line and contacting the first transparent conductive layer where the first hole is disposed; forming a pixel-defining layer and at least one common layer over the pad electrode; and forming a second hole in the pixel-defining layer and the at least one common layer to expose a portion of the pad electrode; and forming a common electrode on the pixel-defining layer, the common electrode overlapping the pad electrode and contacting the pad electrode where the second hole is disposed. The etching of the first transparent conductive layer may include overly etching the first transparent conductive layer by more than an amount of reduction of the mask that occurs in the process of etching the first transparent conductive layer and the first metal layer.

In an embodiment, the first transparent conductive layer may be etched into a pattern that has a width smaller than a width of the mask and having an upper surface completely covered by the mask.

In an embodiment, the first transparent conductive layer may be etched to have a one-side skewed amount of about 0.1 μm or more than the one-side reduction amount of the mask.

In an embodiment, the pad electrode may include a second transparent conductive layer contacting the first transparent conductive layer, and the first transparent conductive layer and the second transparent conductive layer may be formed of a transparent conductive oxide including one or more same elements.

In an embodiment, the first transparent conductive layer may be made of indium-tin oxide (ITO), indium-zinc oxide (IZO), or indium-gallium-zinc oxide (IGZO), and the second transparent conductive layer may be made of indium-tin oxide (ITO).

According to embodiments, a common electrode may be connected to a low-resistance voltage line through a pad electrode. By doing so, it is possible to prevent or reduce a voltage drop in a pixel voltage supplied to the common electrode.

According to embodiments, the voltage line may include a first metal layer and a first transparent conductive layer on the first metal layer, and the pad electrode may include a second transparent conductive layer in contact with the first transparent conductive layer. According to an embodiment, the first transparent conductive layer has a smaller width than the first metal layer and may be located on the inner side of the first metal layer when viewed from the top. Accordingly, in the process of forming the voltage line, the first transparent conductive layer of the voltage line is stably covered by the mask, thereby preventing or reducing by-products that may be generated from the first transparent conductive layer, and improving the yield of the display device.

According to an embodiment, the first transparent conductive layer may be formed of a material that can reduce and/or minimize contact resistance between the voltage line and the pad electrode. For example, the first transparent conductive layer and the second transparent conductive layer may include at least one same element and may include the same transparent conductive oxide or different transparent conductive oxides. By doing so, it is possible to more effectively prevent or reduce a voltage drop in a pixel voltage supplied to the common electrode.

However, effects according to the embodiments are not limited to those described above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view showing a display device according to an embodiment.

FIG. 2 is a schematic plan view showing a display panel according to an embodiment.

FIG. 3 shows a part of the display area according to the embodiment.

FIG. 4 is a schematic cross-sectional view showing a display panel according to an embodiment.

FIG. 5 is a schematic cross-sectional view showing a voltage line, a pad electrode, and a common electrode according to an embodiment.

FIG. 6 is a schematic cross-sectional view showing a display panel according to an embodiment.

FIGS. 7 to 18 are schematic cross-sectional views showing a method of fabricating a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when an element or a layer is referred to as being “on” another element or layer, it can be directly on the other element or layer, or intervening layers may also be present. The same reference numbers indicate the same components throughout the specification.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Features of each of various embodiments may be partially or entirely combined with each other and may technically variously interwork with each other, and respective embodiments may be implemented independently of each other or may be implemented together in association with each other.

Hereinafter, embodiments will be described in detail with reference to the accompanying drawings.

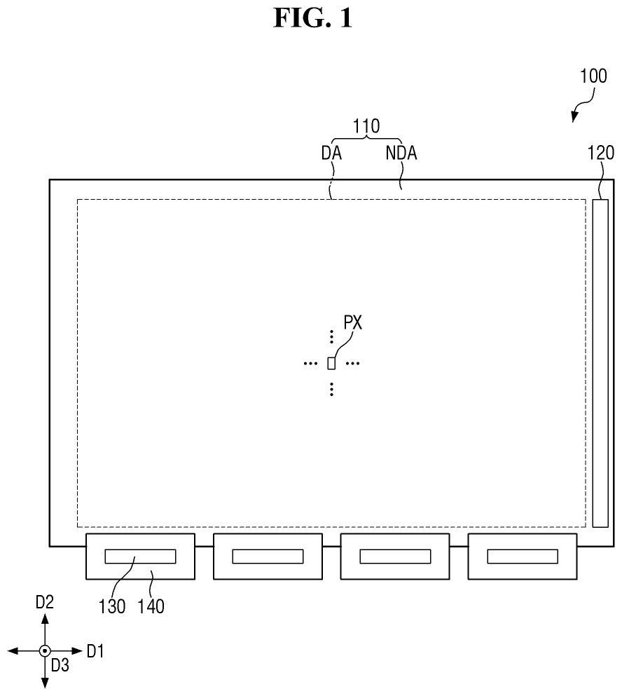

FIG. 1 is a schematic plan view showing a display device 100 according to an embodiment.

Referring to FIG. 1, a display device 100 is for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things. Those listed-above are examples, and the display device 100 may be employed in other electronic devices as well.

According to an embodiment, the display device 100 may be a light-emitting display device such as an organic light-emitting display device including organic light-emitting diodes, a quantum-dot light-emitting display device including quantum-dot light-emitting layer, and an ultra-small light-emitting display device including ultra-small light-emitting diodes such as micro or nano light-emitting diodes (micro LEDs or nano LEDs). It should be understood, however, that the disclosure is not limited thereto. For example, the display device 100 may be other types of display devices than light-emitting display devices. In the following description, a light-emitting display device (for example, an organic light-emitting display device) is disclosed as the display device 100.

The display device 100 may include a display panel 110 including pixels PX, and a first driver 120 and second drivers 130 that supply driving signals to the pixels PX. The display device 100 may further include additional elements. For example, the display device 100 may further include a power supply unit for supplying supply voltages to the pixels PX, the first driver 120 and the second drivers 130, and a timing controller for controlling the operation of the first driver 120 and the second drivers 130, etc.

The display panel 110 may include a display area DA and a non-display area NDA. The display area DA may include pixels PX to display images. The non-display area NDA may be the other area than the display area DA, where no image is displayed in the non-display area NDA. According to the embodiment, the non-display area NDA may be disposed around the display area DA to surround it or may be adjacent to it.

In FIG. 1, a first direction D1, a second direction D2 and a third direction D3 are defined. According to the embodiment, the first direction D1 may be the horizontal direction of the display panel 110, and the second direction D2 may be the vertical direction of the display panel 110. The third direction D3 may refer to the thickness direction of the display panel 110.

According to the embodiment, the display panel 110 may have a rectangular shape when viewed from the top. Although the display panel 110 has the horizontal length larger than the vertical length in FIG. 1, the shape of the display panel 110 is not limited thereto. For example, the display panel 110 may have a shape in which the vertical length is larger than the horizontal length, or may have a square shape, etc. The display panel 110 may include sharp corners or rounded corners.

The shape of the display panel 110 when viewed from the top is not limited to the above-described rectangular shapes but other shapes may be employed. For example, the display panel 110 may have a polygonal shape other than a rectangle, a circular shape, an elliptical shape, or other shapes.

According to the embodiment, the display panel 110 may be substantially flat on the plane defined by the first direction D1 and the second direction D2, and may have a uniform thickness in the third direction D3. By way of example, the display panel 110 may be implemented in a three-dimensional shape having a curved surface, etc.

The display panel 110 may be a rigid display panel that is not substantially deformed, or a flexible display panel that can be deformed, for example, at least partially folded, bent or rolled. The display panel 110 may be provided to the display device 100 without being bent or with being partially bent.

The first driver 120 and the second drivers 130 may generate driving signals for controlling the operation timing and brightness of the pixels PX, and may supply the driving signals to the pixels PX. For example, the first driver 120 may be a gate driver including a scan driver, and may be connected to the pixels PX through the respective gate lines. The first driver 120 may supply gate signals (for example, control signals that control the operation timing of the pixels PX, including scan signals and/or emission control signals) to the pixels PX. The second drivers 130 may be data drivers including source driver circuits and may be connected to the pixels PX through the respective data lines. The second drivers 130 may supply the respective data signals to the pixels PX.

According to an embodiment, at least one of the first driver 120 and the second drivers 130 or a part of the at least one driver may be incorporated into the display panel 110. For example, the first driver 120 or a part of the first driver 120 may be disposed on the substrate SUB of the display panel 110 and may be disposed and/or formed in the non-display area NDA.

Although the first driver 120 is formed on one side or a side of the display area DA (for example, in the non-display area NDA on the right side of the display area DA) in the example shown in FIG. 1, the embodiments are not limited thereto. For example, the first driver 120 may be located (or disposed) only on the other side of the display area DA (for example, in the non-display area NDA on the left side of the display area DA), or located on the both sides of the display area DA (for example, in the non-display area NDA on the left and right sides of the display area DA). By way of example, a part of the first driver 120 may be located in the non-display area NDA, while another part of the first driver 120 may be located in a non-emission area (for example, an area between the emission areas of the pixels PX) in the display area DA.

According to an embodiment, the other one of the first driver 120 and the second drivers 130 or a part of the other driver may be disposed or formed outside the display panel 110 and may be electrically connected to the display panel 110. For example, the second drivers 130 may be implemented with integrated circuit chips and may be disposed on circuit boards 140 electrically connected to the pixels PX of the display panel 110. The second drivers 130 may be implemented as at least one integrated circuit chip and may be mounted on the non-display area NDA of the display panel 110.

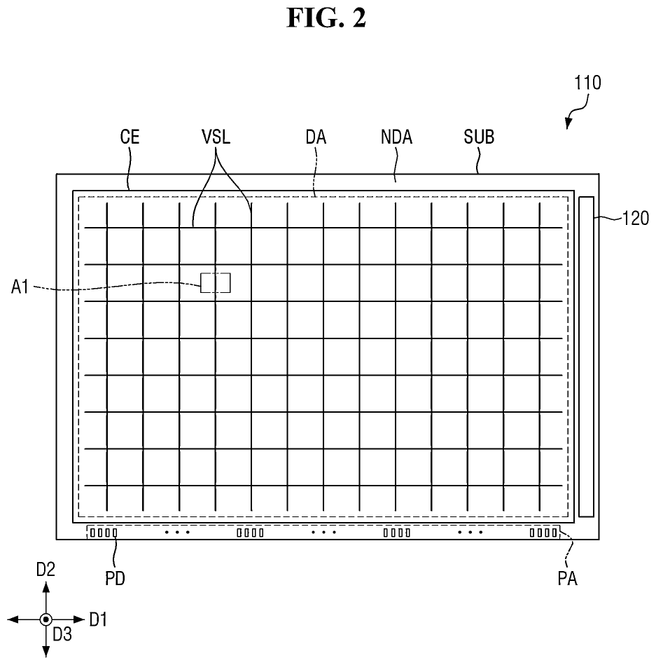

The circuit boards 140 may be disposed on pads (for example, pads PD in FIG. 2) formed on the display panel 110 and connected to the display panel 110 through the pads. According to the embodiment, the circuit board 140 may be, but is not limited to, a flexible printed circuit board (FPCB), a printed circuit board (PCB) or a flexible film such as chip on film (COF). According to an embodiment, the circuit boards 140 may be connected to a timing controller and/or a power supply unit through another circuit board or a connector.

FIG. 2 is a schematic plan view showing the display panel 110 according to the embodiment. For example, FIG. 2 shows an example of the display panel 110 of FIG. 1.

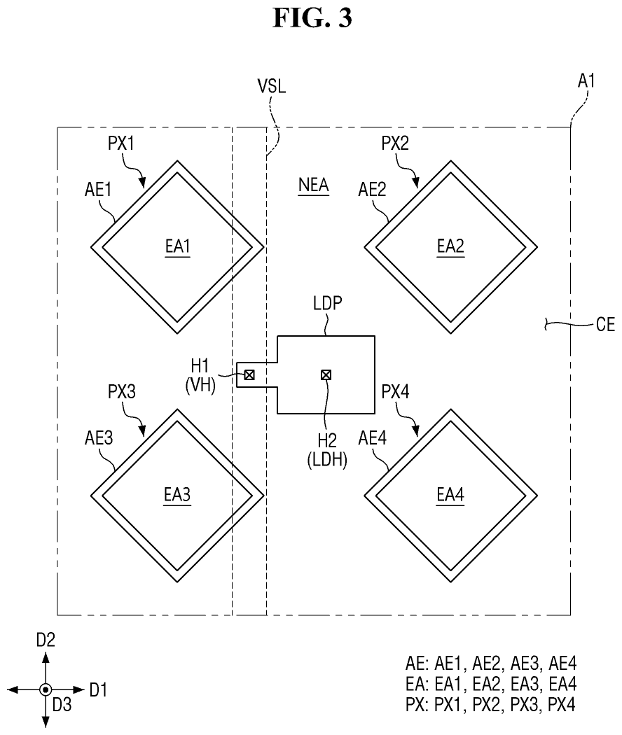

FIG. 3 shows a part of the display area DA according to the embodiment. For example, FIG. 3 shows an example of area A1 in FIG. 2.

Referring to FIGS. 2 and 3 in conjunction with FIG. 1, the display panel 110 may include a substrate SUB and pixels PX disposed on the substrate SUB. The pixels PX may be disposed in the display area DA on the substrate SUB.

The substrate SUB may be a base member for fabricating or providing the display panel 110 and may form a base surface of the display panel 110. The substrate SUB may include the display area DA and the non-display area NDA surrounding the display area DA.

The display area DA may have a variety of shapes according to embodiments. For example, the display area DA may have a rectangular shape, a non-rectangular polygonal shape, a circular shape, an elliptical shape, an irregular shape, or other shapes. According to an embodiment, the display area DA may have a shape that conforms to the shape of the display panel 110.

The pixels PX may be provided and/or arranged and/or disposed in the display area DA. For example, the display area DA may include pixel areas where the pixels PX are disposed. The pixel areas may include emission areas EA, respectively. The display area DA may include the emission areas EA of the pixels PX and the non-emission area NEA located around the emission areas EA. For example, the non-emission area NEA may be located between and/or around the emission areas EA and may surround the emission areas EA.

Each of the pixels PX may include a pixel electrode AE and a common electrode CE. According to the embodiment, the pixel electrode AE may be individually disposed and/or formed in each of the pixels PX corresponding to the emission areas EA of the pixels PX, and the common electrode CE may be shared by the pixels PX. For example, the pixel electrode AE may be individually patterned to be located in each emission area EA, and the common electrode CE may be formed entirely in the display area DA. According to the embodiment, the pixel electrode AE may have a shape and/or size corresponding to the respective emission area EA, and may have an area larger than the emission area EA to be extended to the outside of the emission area EA. According to the embodiment, the common electrode CE may have a shape and/or size corresponding to the display area DA, and may have an area larger than the display area DA to be extended to the outside of the display area DA.

According to the embodiment, the display panel 110 may be a light-emitting display panel (for example, an organic light-emitting display panel), and each of the pixels PX may include a light-emitting element located in the respective emission area EA. The pixel electrode AE may be a first electrode of a light-emitting element disposed in each of the pixels PX, and the common electrode CE may be a second electrode of the light-emitting element. For example, the pixel electrode AE may be an anode electrode (or cathode electrode), and the common electrode CE may be a cathode electrode (or anode electrode). An emissive layer (for example, an organic light-emitting layer) may be disposed between the pixel electrode AE of each of the pixels PX and the common electrode CE. Each of the pixels PX may include an emission area EA in which a pixel electrode AE, an emissive layer and a common electrode CE are provided.

According to an embodiment, each of the pixels PX may further include a pixel circuit connected to the respective light-emitting element. In the following description of the embodiments, the term “connection” may encompass electrical connection and/or physical connection. The pixel circuit may include circuit elements for controlling the light-emitting elements (for example, transistors including a driving transistor and a switching transistor, and capacitors including a storage capacitor). The pixel areas may include emission areas EA provided with light-emitting elements and pixel circuit areas provided with pixel circuits. The emission area EA and the pixel circuit area of each pixel PX may or may not overlap each other.

Lines connected to the pixels PX may be further disposed in the display area DA. FIGS. 2 and 3 show voltage lines VSL connected to the common electrode CE as an example of the above lines. According to embodiments, the voltage lines VSL may be connected to the common electrode CE through at least one pad electrode LDP disposed in the display area DA.

According to an embodiment, the voltage lines VSL may include a low-resistance conductive material. By supplying the pixel voltage to the common electrode CE through the voltage lines VSL, it is possible to prevent, reduce and/or minimize a voltage drop in the pixel voltage. Accordingly, it is possible to prevent or reduce luminance change due to a voltage drop in the pixel voltage, and the image quality of the display device 100 can be improved.

According to an embodiment, the voltage lines VSL may be arranged in a mesh pattern in the display area DA, but the disclosure is not limited thereto. For example, the position, the shape and/or the size of the voltage lines VSL may vary in a variety of ways depending on the design space that can be obtained in the display area DA (for example, the design space that can be obtained in the layer where the voltage lines VSL are disposed in the display panel 110).

According to the embodiment, the voltage lines VSL may be disposed in a panel circuit layer located below the pixel electrodes AE and the pad electrode LDP. The voltage lines VSL may overlap the emission area EA of at least one pixel PX or may be disposed in the non-emission area NEA so that they do not overlap the emission areas EA of the pixels PX.

The voltage lines VSL may be connected to at least one pad PD (for example, a power pad that supplies a pixel voltage (for example, a low-level pixel voltage)) located in a pad area PA. For example, the voltage lines VSL may be extended to the non-display area NDA outside the display area DA and may be directly connected to the at least one pad PD, or may be connected to the at least one pad PD through a connection line formed in the non-display area NDA.

At least one pad electrode LDP may be further disposed in the display area DA. For example, at least one pad electrode LDP may be disposed in the non-emission area NEA. The pad electrode LDP may connect the voltage lines VSL with the common electrode CE disposed in different layers in the display panel 110. For example, the pad electrode LDP may be an intermediate electrode that connects the voltage lines VSL with the common electrode CE, and may be disposed in an intermediate layer located between the lower layer provided with the voltage line VSL and the upper layer provided with the common electrode CE in the display panel 110. According to an embodiment, the pad electrode LDP may be formed simultaneously with the pixel electrode AE. For example, the pad electrode LDP may be formed in the same layer as the pixel electrode AE and spaced apart from the pixel electrode AE.

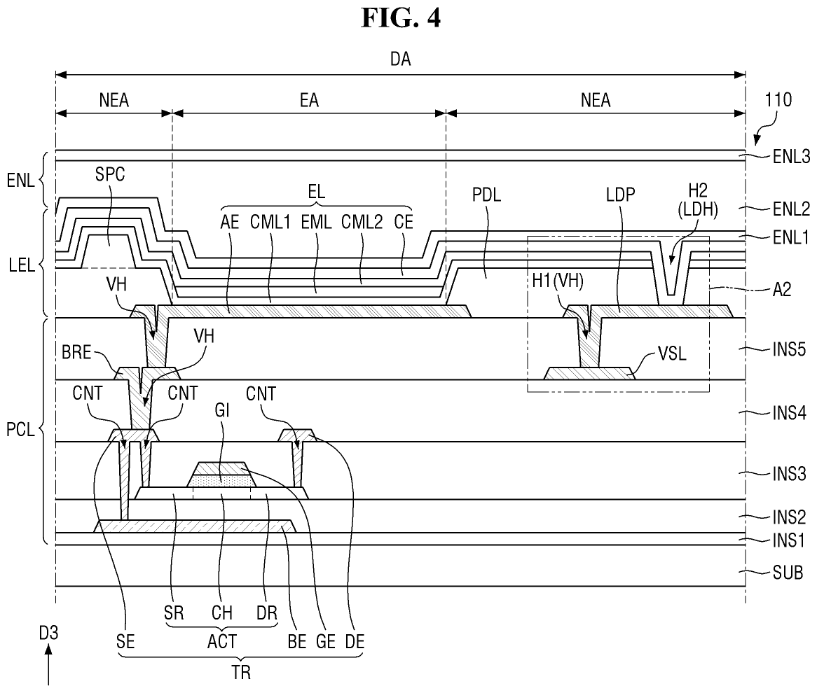

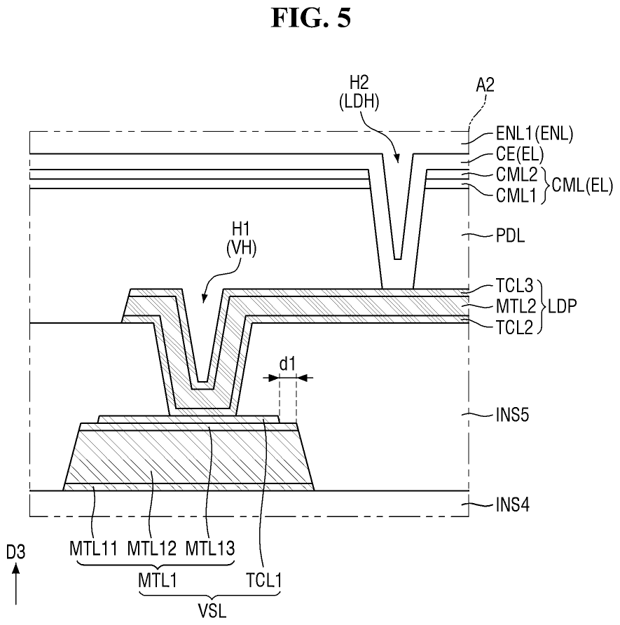

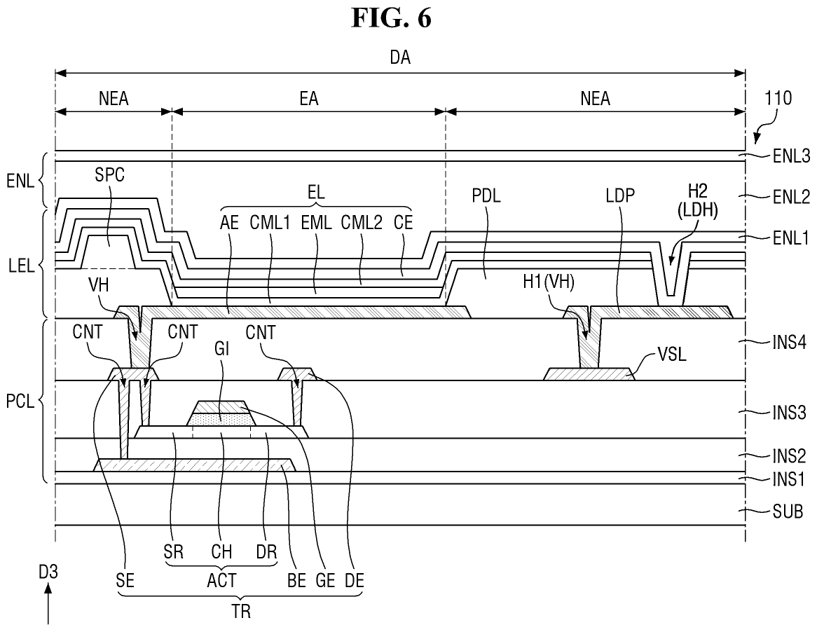

The pad electrode LDP may overlap the voltage line VSL and may be connected to the voltage line VSL through a first hole H1. The first hole H1 may be formed in an insulating layer disposed between the voltage line VSL and the pad electrode LDP (for example, the fifth insulating layer INS5 in FIGS. 4 and 5 or the fourth insulating layer INS4 in FIG. 6) such that it penetrates the insulating layer to expose a part of the voltage line VSL. According to the embodiment, the first hole H1 may be a via hole VH or a contact hole formed in the insulating layer by an etching process using a mask.

The pad electrode LDP may overlap the common electrode CE and may be connected to the common electrode CE through a second hole H2. The second hole H2 may be formed in an insulating layer between the pad electrode LDP and the common electrode CE (for example, the pixel-defining layer PDL of FIGS. 4 to 6) such that it penetrates the insulating layer to expose a part of the pad electrode LDP. The second hole H2 may be located in the non-emission area NEA. According to an embodiment, the second hole H2 may be a laser drilling hole LDH formed by a laser drilling technique using laser, and the pad electrode LDP may be a laser drilling pad connected to the common electrode CE by the laser drilling hole LDH.

According to the embodiment, pad electrodes LDP spaced apart from each other may be disposed in the display area DA. According to an embodiment, each of the pad electrodes LDP may be located between the emission areas EA of adjacent pixels PX. For example, one pad electrode LDP located in the display area DA may be located between the emission areas EA of the first, second, third and fourth pixels PX1, PX2, PX3 and PX4 adjacent to each other (for example, the first, second, third and fourth emission areas EA1, EA2, EA3 EA4), and may be spaced apart from the pixel electrodes AE of the first, second, third and fourth pixels PX1, PX2, PX3 and PX4 (for example, the first, second, third and fourth pixel electrodes AE1, AE2, AE3 and AE4). The number, arrangement density (or resolution), shape, size and/or location of the pad electrodes LDP disposed in the display area DA may vary depending on embodiments.

According to an embodiment, each of the first, second, third and fourth pixels PX1, PX2, PX3 and PX4 may emit light of a selectable color. For example, each of the first, second, third and fourth pixels PX1, PX2, PX3 and PX4 may emit light of red, green, blue, white, or other color.

Although the positions and shapes of the emission areas EA and the pixel electrodes AE of the first, second, third and fourth pixels PX1, PX2, PX3 and PX4 are shown in FIG. 3, the embodiments are not limited thereto. For example, the shape, arrangement structure and/or size of the emission areas EA and/or the pixel electrodes AE of the first, second, third and fourth pixels PX1, PX2, PX3 and PX4 may be altered in various ways depending on the embodiments.

The non-display area NDA may include a pad area PA where the pads PD are disposed. According to an embodiment, the non-display area NDA may further include a driver circuit area located on at least one side or a side of the display area DA. At least one driver, pads PD and/or lines may be disposed in the non-display area NDA.

At least one driver for driving the pixels PX or a part of the driver may be disposed in the driver circuit area. For example, circuit elements forming the first driver 120 (for example, driving transistors and driving capacitors forming stage circuits of the first driver 120) may be disposed in the driver circuit area on the substrate SUB. According to the embodiment, the circuit elements of the first driver 120 may be formed in the display panel 110 together with the circuit elements of the pixels PX.

At least one circuit board 140 may be disposed and/or bonded on the pad area PA. According to the embodiment, circuit boards 140 connected to different pads PD may be disposed on the pad area PA. The pads PD may include signal pads and power pads for transmitting the driving signals and the supply voltages required for driving the pixels PX and/or the first driver 120 to the inside of the display panel 110.

FIG. 4 is a schematic cross-sectional view showing the display panel 110 according to the embodiment. For example, FIG. 4 is a schematic cross-sectional view showing a part of the display area DA of the display panel 110, in which a light-emitting element EL is located in an emission area EA of a pixel PX, a part of a voltage line VSL is located around the emission area EA, and a pad electrode LDP is connected to the voltage line VSL. FIG. 4 shows a light-emitting display panel including a light-emitting element EL (for example, an organic light-emitting diode) as an example of the display panel 110 to which the embodiments can be applied.

Referring to FIG. 4 in conjunction with FIGS. 1 to 3, the display panel 110 may include a substrate SUB (also referred to as a “base layer”), a panel circuit layer PCL, a light-emitting element layer LEL, and an encapsulation layer ENL. The panel circuit layer PCL, the light-emitting element layer LEL and the encapsulation layer ENL may be disposed on the substrate SUB such that they overlap one another. For example, in the display area DA, the panel circuit layer PCL, the light-emitting element layer LEL and the encapsulation layer ENL may be sequentially disposed on the substrate SUB in the third direction D3. It should be understood, however, that the embodiments are not limited thereto. The positions of the panel circuit layer PCL, the light-emitting element layer LEL and/or the encapsulation layer ENL may be changed.

According to an embodiment, the display panel 110 may further include additional elements provided on and/or under or below the encapsulation layer ENL. For example, the display panel 110 may further include at least one of a sensor layer (for example, a touch sensor layer), an optical layer (for example, a color filter layer and/or a wavelength conversion layer), and a protective layer (for example, a protective film, an insulating layer, an upper substrate and/or a window).

The substrate SUB may be a base member for forming the display panel 110 and may be a rigid or flexible substrate (or film). According to an embodiment, the substrate SUB may be a substrate that may include an insulating material such as glass and is rigid, which may not be bendable. By way of example, the substrate SUB may be a flexible substrate that may include polyimide or other insulating material and allows deformation such as bending, folding or rolling, and may be bent or not bent. The type and/or material of the substrate SUB may be altered depending on the embodiments.

The panel circuit layer PCL may include circuit elements of the pixels PX located in the display area DA (for example, transistors TR including a transistor TR connected to the light-emitting element EL of each pixel PX and capacitors), and lines located in the display area DA and/or the non-display area NDA (for example, a variety of voltage lines and signal lines, including the voltage lines VSL). According to an embodiment, the panel circuit layer PCL may further include circuit elements of the first driver 120 and/or additional conductive patterns (for example, bridge patterns).

FIG. 4 shows a transistor TR provided to one pixel PX and connected to the light-emitting element EL of the pixel PX as an example of circuit elements that can be provided to the panel circuit layer PCL. The transistor TR of FIG. 4 may be a driving transistor or a switching transistor provided in the pixel circuit of that pixel PX.

The panel circuit layer PCL may include conductive layers provided with circuit elements and lines, and at least one semiconductor layer. Electrodes forming circuit elements of the panel circuit layer PCL, conductive patterns (for example, bridge electrodes BRE) connected to the electrodes and/or lines, and/or lines, etc. may be provided in the conductive layers. The active layers ACT of the transistors TR in the panel circuit layer PCL may be disposed in the semiconductor layer.

The electrodes, the conductive patterns and/or the lines provided in the panel circuit layer PCL may include at least one conductive material. For example, the electrodes, the conductive patterns and/or the lines provided in the panel circuit layer PCL may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg) and other metals, an alloy thereof, or other conductive material. According to an embodiment, the electrodes, the conductive patterns and/or the lines disposed in the same conductive layer may be formed simultaneously using the same conductive material. According to an embodiment, the electrodes, the conductive pattern and/or the lines provided in the conductive layers of the panel circuit layer PCL may have single-layer or multi-layer structures.

The panel circuit layer PCL may further include insulating layers and/or insulating patterns disposed on the substrate SUB. For example, the panel circuit layer PCL may include a first insulating layer INS1, a second insulating layer INS2, and a gate insulator GI, a third insulating layer INS3, a fourth insulating layer INS4 and a fifth insulating layer INS5 sequentially disposed on the substrate SUB in the third direction D3.

The first insulating layer INS1 may be disposed on the substrate SUB. The first insulating layer INS1 may include an inorganic insulating layer. The first insulating layer INS1 can protect the pixels PX from moisture permeating through the substrate SUB, which is vulnerable to moisture permeation. The first insulating layer INS1 disposed on the substrate SUB may be optional. For example, the display panel 110 may or may not include the first insulating layer INS1.

The second insulating layer INS2 may be disposed on the first insulating layer INS1 (or the substrate SUB). The second insulating layer INS2 may cover the patterns of the first conductive layer disposed on the first insulating layer INS1 (or substrate SUB) (for example, the electrodes of the first conductive layer including the bottom electrode BE of the transistor TR the conductive patterns, and/or at least one line).

The gate insulator GI may be disposed above the second insulating layer INS2. The gate insulator GI may cover at least a part of the patterns of the semiconductor layer (for example, the semiconductor patterns of the semiconductor layer including the active layer ACT of the transistor TR) disposed on the second insulating layer INS2.

The third insulating layer INS3 may be disposed on the second insulating layer INS2. The third insulating layer INS3 may cover the patterns of the semiconductor layer disposed on the second insulating layer INS2 (for example, semiconductor patterns of the semiconductor layer including the active layer ACT of the transistor TR), the gate insulator GI, and patterns of the second conductive layer disposed on the gate insulator GI (for example, electrodes of the second conductive layer including the gate electrode GE of the transistor TR, conductive patterns and/or at least one line).

The fourth insulating layer INS4 may be disposed on the third insulating layer INS3. The fourth insulating layer INS4 may cover patterns of the third conductive layer disposed on the third insulating layer INS3 (for example, electrodes of the third conductive layer including the source electrode SE and/or drain electrode DE of the transistor TR, conductive patterns and/or at least one line).

According to an embodiment, the fourth insulating layer INS4 may be a single-layer or multi-layer insulating layer including an organic insulating layer, and may or may not include an inorganic insulating layer. For example, the fourth insulating layer INS4 may have a multi-layer structure including an inorganic film and an organic film sequentially disposed on the third insulating layer INS3, or may include only an organic film without any inorganic film.

The fifth insulating layer INS5 may be disposed on the fourth insulating layer INS4. The fifth insulating layer INS5 may cover the patterns of the fourth conductive layer disposed on the fourth insulating layer INS4 (for example, the electrodes of the fourth conductive layer including the bridge electrode BRE, the conductive patterns, and/or at least one line including the voltage line VSL).

According to an embodiment, the fifth insulating layer INS5 may be a single-layer or multi-layer insulating layer including an organic insulating layer, and may or may not include an inorganic insulating layer. For example, the fifth insulating layer INS5 may have a multi-layer structure including an inorganic film and an organic film sequentially disposed on the fourth insulating layer INS4, or may include only an organic film without any inorganic film.

According to an embodiment, each of the first insulating layer INS1, the second insulating layer INS2, the gate insulator GI and the third insulating layer INS3 may include at least one inorganic insulating layer including an inorganic insulating material (for example, silicon nitride, silicon oxide, silicon oxynitride, titanium oxide, aluminum oxide, or other inorganic insulating materials). For example, each of the first insulating layer INS1, the second insulating layer INS2, the gate insulator GI, and the third insulating layer INS3 may be a single-layer or multi-layer inorganic insulating layer. According to an embodiment where at least one of the fourth insulating layer INS4 and the fifth insulating layer INS5 may include an inorganic film, the inorganic film may include at least one inorganic insulating material mentioned above.

According to an embodiment, each of the fourth insulating layer INS4 and the fifth insulating layer INS5 may include at least one organic insulating layer including an organic insulating material (for example, an acrylic resin, an epoxy resin, a phenolic resin, a polyamide resin, a polyimide resin, or other organic insulating materials). The surfaces (for example, upper surfaces) of the fourth insulating layer INS4 and the fifth insulating layer INS5 may be substantially flat.

According to an embodiment, at least one insulating layer provided in the panel circuit layer PCL may be disposed entirely in the display area DA. For example, the first insulating layer INS1, the second insulating layer INS2, the third insulating layer INS3, the fourth insulating layer INS4 and the fifth insulating layer INS5 may be disposed entirely in the display area DA.

According to the embodiment, the gate insulator GI may be partially disposed in only a portion of each pixel area and/or the display area DA. For example, the gate insulator GI may be individually patterned in each transistor area where at least one transistor TR is located, and may be disposed only on a portion of the active layer ACT provided to the transistor TR while exposing the other portions of the active layer ACT. For example, the gate insulator GI may be disposed between a part of the active layer ACT including the channel region CH and the gate electrode GE and may not be disposed on the other portions of the active layer ACT including the source region SR and drain region DR. It should be understood, however, that the embodiments are not limited thereto. For example, the gate insulator GI may be entirely disposed in the transistor areas and/or the display area DA.

The transistor TR may include an active layer ACT and a gate electrode GE (for example, a top-gate electrode) disposed on a part of the active layer ACT. According to an embodiment, the transistor TR may further include at least one of the source electrode SE and the drain electrode DE. For example, the transistor TR may further include the source electrode SE connected to the source region SR of the active layer ACT and the drain electrode DE connected to the drain region DR of the active layer ACT. By way of example, the transistor TR may not include separate source electrode and/or drain electrode, and the source region SR and/or drain region DR of the active layer ACT may be connected to other circuit elements, lines and/or conductive patterns to work as the source electrode and/or drain electrode of the transistor TR.

According to an embodiment, the transistor TR may further include a bottom electrode BE (for example, bottom-gate electrode) disposed below the active layer ACT. According to the embodiment, the bottom electrode BE may be connected to one electrode of the transistor TR and may be used as a back-gate electrode to adjust the characteristics of the transistor TR. By disposing the bottom electrode BE below the active layer ACT, it is possible to block external light from entering the channel region CH of the active layer ACT, and the operating characteristics of the transistor TR can be stabilized.

According to an embodiment, the transistor TR may be an n-type transistor. As an example, the transistor TR may be an n-type oxide transistor.

The bottom electrode BE may be disposed between the first insulating layer INS1 and the second insulating layer INS2. For example, the bottom electrode BE may be disposed on the first insulating layer INS1 and covered with the second insulating layer INS2. The bottom electrode BE may overlap the active layer ACT and the gate electrode GE. For example, the bottom electrode BE may be disposed below the active layer ACT such that it overlap at least a part of the active layer ACT including the channel region CH, and may be opposed to the gate electrode GE with the active layer ACT disposed therebetween.

According to the embodiment, the bottom electrode BE may be connected to the source electrode SE or the gate electrode GE of the transistor TR. For example, the transistor TR may be a driving transistor of the pixel PX. The bottom electrode BE of the transistor TR may be connected to the source electrode SE of the transistor TR through at least one contact hole CNT penetrating the second insulating layer INS2 and the third insulating layer INS3. By way of example, the transistor TR may be a switching transistor of the pixel PX, and the bottom electrode BE of the transistor TR may be connected to the gate electrode GE of the transistor TR.

The active layer ACT may be disposed between the second insulating layer INS2 and the gate insulator GI. For example, the active layer ACT may be disposed on the second insulating layer INS2 and covered with the gate insulator GI and the third insulating layer INS3.

The active layer ACT may include a channel region CH and a source region SR and a drain region DR spaced apart from each other with the channel region CH therebetween. For example, the source region SR and the drain region DR may be located on the both sides of the channel region CH. The channel region CH may not be conductive and maintain semiconductor properties. The source region SR and the drain region DR are conductive regions and may have a higher carrier concentration (for example, electron concentration) than the channel region CH.

The active layer ACT may overlap the bottom electrode BE and the gate electrode GE. For example, a part of the active layer ACT including the channel region CH may overlap the bottom electrode BE and the gate electrode GE.

According to an embodiment, the active layer ACT may include oxide semiconductor. For example, the active layer ACT may include an oxide semiconductor including at least one of indium (In), gallium (Ga), zinc (Zn), tin (Sn) and hafnium (Hf), or other oxide semiconductor. According to an embodiment, the active layer ACT may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), indium-tin-gallium-zinc oxide (ITGZO), or other oxide semiconductors.

The gate insulator GI may be disposed on the active layer ACT. According to the embodiment, the gate insulator GI may be disposed on only a part of the active layer ACT but not on other parts of the active layer ACT. For example, the gate insulator GI may be disposed on a part of the active layer ACT including the channel region CH and may expose the source region SR and drain region DR of the active layer ACT.

As the gate insulator GI exposes the source region SR and drain region DR, the source region SR and drain region DR can become conductive properly and/or readily during the process of fabricating the display panel 110. For example, in etching the gate insulator GI so that at least a part of each of the source region SR and the drain region DR is exposed, oxygen-vacancies may occur in the source region SR and the drain region DR by an etching gas or the like within the spirit and the scope of the disclosure. Accordingly, the source region SR and drain region DR can become conductive properly in a subsequent process (for example, a process of forming the third insulating layer INS3, etc.) without performing a separate doping process.

The gate electrode GE may be disposed between the gate insulator GI and the third insulating layer INS3. For example, the gate electrode GE may be disposed on the gate insulator GI and covered with the third insulating layer INS3.

The gate electrode GE may be disposed above the active layer ACT to overlap the channel region CH. The gate electrode GE and the active layer ACT may be separated and/or spaced apart from each other with the gate insulator GI disposed therebetween.

The third insulating layer INS3 may be disposed on the gate electrode GE. The third insulating layer INS3 may cover the active layer ACT, the gate insulator GI and the gate electrode GE.

The source electrode SE and the drain electrode DE may be disposed between the third insulating layer INS3 and the fourth insulating layer INS4. For example, the source electrode SE and the drain electrode DE may be disposed on the third insulating layer INS3 and covered with the fourth insulating layer INS4.

The source electrode SE may be connected to a part of the active layer ACT. For example, the source electrode SE may be connected to the source region SR of the active layer ACT through at least one contact hole CNT penetrating the third insulating layer INS3. According to an embodiment, the source electrode SE may be further connected to the bottom electrode BE through another contact hole CNT penetrating the second insulating layer INS2 and the third insulating layer INS3.

The drain electrode DE may be connected to another part of the active layer ACT. For example, the drain electrode DE may be connected to the drain region DR of the active layer ACT through at least one contact hole CNT penetrating the third insulating layer INS3.

According to an embodiment, at least one transistor TR provided in each pixel PX may be connected to a bridge electrode BRE disposed on the fourth insulating layer INS4 and may be connected to the light-emitting element EL of that pixel PX through the bridge electrode BRE. For example, the source electrode SE (or drain electrode DE) of at least one transistor TR provided in each pixel PX may be connected to the bridge electrode BRE on the fourth insulating layer INS4 through at least one via hole VH (or a contact hole) penetrating the fourth insulating layer INS4.

The bridge electrode BRE may be disposed between the fourth insulating layer INS4 and the fifth insulating layer INS5. For example, the bridge electrode BRE may be disposed on the fourth insulating layer INS4 and covered with the fifth insulating layer INS5. The bridge electrode BRE may be connected to the pixel electrode AE provided in the light-emitting element layer LEL through at least one via hole VH (or contact hole) penetrating the fifth insulating layer INS5.

According to the embodiment, a voltage line VSL may be further disposed between the fourth insulating layer INS4 and the fifth insulating layer INS5. For example, the voltage line VSL may be disposed on the fourth insulating layer INS4 and covered with the fifth insulating layer INS5.

According to the embodiment, the bridge electrode BRE and the voltage line VSL may be formed together. For example, the bridge electrode BRE and the voltage line VSL may be formed in the same layer in the panel circuit layer PCL using the same conductive material. For example, a single-layer or multi-layer conductive film may be formed on the fourth insulating layer INS4, and the conductive film is etched via an etching process using a mask so that the bridge electrode BRE and the voltage line VSL are separated from each other.

The light-emitting element layer LEL may be disposed on the panel circuit layer PCL. For example, the light-emitting element layer LEL may be disposed on the fifth insulating layer INS5 and may be located at least in the display area DA.

The light-emitting element layer LEL may include a light-emitting element EL of each of the pixels PX. For example, the light-emitting element layer LEL may include a pixel-defining layer PDL (also referred to as a “bank” or “sixth insulating layer”) that partitions the emission area EA of each of the pixels PX and light-emitting elements EL each located in the emission area EA. According to the embodiment, the light-emitting element layer LEL may further include a spacer SPC disposed on a portion of the pixel-defining layer PDL.

Each of the light-emitting element EL may include a pixel electrode AE located in the respective emission area EA (for example, the first electrode or anode electrode of the light-emitting element EL), an emissive layer EML sequentially disposed on the pixel electrode AE, and a common electrode CE (for example, the second electrode or cathode electrode of the light-emitting element EL). The pixel electrode AE may be connected to at least one transistor TR included in that pixel PX. According to an embodiment, the light-emitting element EL may further include at least one common layer. For example, the light-emitting element EL may further include at least one of a first common layer CML1 disposed between the pixel electrode AE and the emissive layer EML and formed entirely in the display area DA (for example, a hole injection layer and/or a hole transport layer, etc.), and a second common layer CML2 disposed between the emissive layer EML and the common electrode CE and formed entirely in the display area DA (for example, an electron injection layer and/or an electron transport layer, etc.).

The pixel electrode AE may be disposed on the fifth insulating layer INS5. For example, the pixel electrode AE may be disposed between the fifth insulating layer INS5 and the pixel-defining layer PDL.

The pixel electrode AE may be a single-layer or multi-layer electrode including or containing at least one conductive material. According to an embodiment, the display panel 110 may be a top-emission display panel, and the pixel electrode AE may include a reflective electrode layer with high reflectivity (for example, the second metal layer MTL2 in FIG. 4).

According to embodiments, a pad electrode LDP may be further disposed between the fifth insulating layer INS5 and the pixel-defining layer PDL. For example, the pad electrode LDP may be disposed on the fifth insulating layer INS5 and covered with the pixel-defining layer PDL.

According to the embodiment, the pixel electrode AE and the pad electrode LDP may be spaced apart from each other in the same layer in the display panel 110 and may be formed together. For example, the pixel electrode AE and the pad electrode LDP may be formed simultaneously in the same layer of the light-emitting element layer LEL using the same conductive material. According to the embodiment, a single-layer or multi-layer conductive film may be formed on the fifth insulating layer INS5, and the conductive film is etched via an etching process using a mask so that the pixel electrode AE and the pad electrode LDP are separated from each other. For example, the pixel electrode AE may be formed to be located in the respective emission area EA, and the pad electrode LDP may be formed to be located in a part of the non-emission area NEA.

The pad electrode LDP may overlap the voltage line VSL and may be connected to the voltage line VSL through a first hole H1 penetrating the fifth insulating layer INS5 (for example, at least one via hole VH or contact hole penetrating the fifth insulating layer INS5).

The emissive layer EML may be disposed on the pixel electrode AE. For example, the emissive layer EML may be disposed between the pixel electrode AE and the common electrode CE. The emissive layer EML may include a high molecular material or a low molecular material. Light emitted from the emissive layer EML may contribute to displaying images.

The common electrode CE may be disposed on the emissive layer EML. According to the embodiment, the common electrode CE may be a common film formed over the entire display area DA to cover the emissive layer EML and the pixel-defining layer PDL. According to an embodiment, the display panel 110 may be a top-emission display panel, and the common electrode CE may be transparent or translucent.

According to the embodiments, the common electrode CE may overlap the pad electrode LDP and may be connected to the pad electrode LDP through a second hole H2 penetrating the pixel-defining layer PDL (for example, at least one laser drilling hole LDH penetrating the pixel-defining layer PDL). In the display panel 110 including at least one common layer disposed between the pixel-defining layer PDL and the common electrode CE, the second hole H2 may be formed to further penetrate the common layer. For example, the second hole H2 may be formed to penetrate the pixel-defining layer PDL, the first common layer CML1 and the second common layer CML2 and may connect the pad electrode LDP with and the common electrode CE. Accordingly, the pixel voltage (for example, low-level pixel voltage or cathode voltage) applied to the voltage line VSL may be applied to the common electrode CE.

The pixel-defining layer PDL may have openings associated with the emission areas EA and may surround the emission areas EA. For example, the pixel-defining layer PDL may be formed to cover edges of the pixel electrode AE of the light-emitting element EL, and may be open to expose the remaining portion of the pixel electrode AE. The area where the exposed pixel electrode AE and the emission layer EML overlap each other may be the emission area EA of each pixel PX. According to an embodiment, the pixel-defining layer PDL may include at least one organic insulating layer including or containing an organic insulating material.

The spacer SPC may be disposed on a part of the pixel-defining layer PDL. The spacer SPC may include at least one organic insulating layer including or containing an organic insulating material. The spacer SPC may include the same material as the pixel-defining layer PDL or may include a different material from the pixel-defining layer PDL. The pixel-defining layer PDL and the spacer SPC may be formed sequentially via the respective mask processes, or may be formed simultaneously and/or integrally using a halftone mask.

The encapsulation layer ENL may be disposed on the light-emitting element layer LEL. The encapsulation layer ENL may cover the light-emitting element layer LEL in the display area DA and may be extended to the non-display area NDA to be in contact with the panel circuit layer PCL. The encapsulation layer ENL can block the permeation of oxygen or moisture into the light-emitting element layer LEL and can alleviate electrical and/or physical shock on the panel circuit layer PCL and the light-emitting element LEL.

According to an embodiment, the encapsulation layer ENL may include a first encapsulation layer ENL1, a second encapsulation layer ENL2, and a third encapsulation layer ENL3 sequentially disposed on the emission material layer LEL. Each of the first encapsulation layer ENL1 and the third encapsulation layer ENL3 may be an inorganic encapsulation layer including or containing an inorganic material. The second encapsulation layer ENL2 may be an organic encapsulation layer including or containing an organic material.

FIG. 5 is a schematic cross-sectional view showing a voltage line VSL, a pad electrode LDP, and a common electrode CE according to an embodiment. For example, FIG. 5 shows an example of area A2 in FIG. 4.

Referring to FIG. 5 in conjunction with FIGS. 1 to 4, the voltage line VSL may include a first metal layer MTL1 and a first transparent conductive layer TCL1 disposed on the first metal layer MTL1. According to the embodiment, the first transparent conductive layer TCL1 may be disposed directly on the first metal layer MTL1.

The first metal layer MTL1 may be made of a single or multi-layer metal layer. According to the embodiment, the first metal layer MTL1 may have a multi-layer structure including a first layer MTL11 including or containing a first metal, a second layer MTL12 disposed on the first layer MTL11 and including or containing a second metal, and a third layer MTL13 disposed on the second layer MTL12 and including or containing a third metal. The second metal may be a different metal from the first and third metals. The third metal may be the same material as or a different metal from the first metal. According to an embodiment, in order to increase fabrication efficiency, the third metal may be the same metal as the first metal.

The first layer MTL11 may include or contain the first metal suitable for protecting the second layer MTL12 and improving adhesion. For example, the first metal may be, but is not limited to, titanium (Ti).

The second layer MTL12 may include or contain the second metal having high conductivity and may have a relatively large thickness compared to the first layer MTL11 and the third layer MTL13. According to an embodiment, the second metal may be a metal suitable for ready patterning by dry etching, etc. For example, the second metal may be, but is not limited to, aluminum (Al).

The third layer MTL13 may include or contain the third metal suitable for protecting the second layer MTL12 and improving adhesion and/or contact resistance. For example, the third metal may be, but is not limited to, titanium (Ti). According to an embodiment, in case that the first layer MTL11, the second layer MTL12 and the third layer MTL13 are made of titanium (Ti), aluminum (Al) and titanium (Ti), respectively, the first metal layer MTL1 may have a triple-layer structure of Ti/Al/Ti.

The first transparent conductive layer TCL1 may include a conductive material suitable for lowering the contact resistance between the voltage line VSL and the pad electrode LDP. As an example, the first transparent conductive layer TCL1 may include the same conductive material as the conductive material forming the lower layer of the pad electrode LDP in contact with the voltage line VSL (for example, a conductive material forming a second transparent conductive layer TCL2) or may include a conductive material that has a similar work function with the conductive material forming the lower layer of the pad electrode LDP.

According to an embodiment, the first transparent conductive layer TCL1 and the second transparent conductive layer TCL2 may be made of the same or different types of conductive materials that may include or contain a selectable element. As an example, the first transparent conductive layer TCL1 and the second transparent conductive layer TCL2 may be made of transparent conductive oxide (TCO) and may include one or more same elements.

According to the embodiments, the first transparent conductive layer TCL1 may have a narrower width than the first metal layer MTL1, and the area where the first transparent conductive layer TCL1 is formed may be located inside the first metal layer MTL1 when viewed from the top. For example, with respect to the contact surface between the first transparent conductive layer TCL1 and the first metal layer MTL1, at one end or an end (for example, the left end or the right end) of the voltage line VSL, the end of the first transparent conductive layer TCL1 may be spaced apart from the end of the first metal layer MTL1 by a first distance d1 and may be located more to the inside. For example, in the width direction of the voltage line VSL, the first metal layer MTL1 may protrude from the both sides of the first transparent conductive layer TCL1, and the voltage line VSL may include steps formed at the boundary between the first metal layer MTL1 and the first transparent conductive layer TCL1.

The first distance d1 may be a process margin that allows the first transparent conductive layer TCL1 to be stably covered by a mask until the process of etching the voltage line VSL including the process of etching the first transparent conductive layer TCL1 and the first metal layer MTL1 (or an etching process for a multi-layer conductive film to form the voltage line VSL) is completed in the etching process for patterning the voltage line VSL and the like within the spirit and the scope of the disclosure. For example, the first distance d1 may be equal to or greater than about 0.1 μm. Accordingly, even if a process error (for example, a process error within about 0.1 μm) occurs during the etching process for patterning the voltage line VSL, the first transparent conductive layer TCL1 of the VR line VSL can be stably covered with a mask until the etching process is completed. Accordingly, by preventing the first transparent conductive layer TCL1, which was etched earlier, from being exposed during the etching process of the first metal layer MTL1, etc., it is possible to prevent contamination of the process chamber and/or the display panel 110 under fabrication due to by-products which may be generated if the first transparent conductive layer TCL1 is exposed. In this manner, it is possible to prevent defects in the display panel 110 and to increase fabrication efficiency. According to an embodiment, the first distance d1 may be in a range of about 0.1 μm to about 0.2 μm. By controlling the first distance d1 within about 0.2 μm, the fabrication efficiency can be increased by appropriately limiting the thickness and/or the etching process time of the first transparent conductive layer TCL1.

The pad electrode LDP may be disposed on an insulating layer over the voltage line VSL, for example, the fifth insulating layer INS5. The pad electrode LDP may include a second transparent conductive layer TCL2 and a second metal layer MTL2 disposed on the second transparent conductive layer TCL2. According to the embodiment, the pad electrode LDP may further include a third transparent conductive layer TCL3 disposed on the second metal layer MTL2.

The pad electrode LDP may be in contact with the first transparent conductive layer TCL1 of the voltage line VSL where the first hole H1 of the fifth insulating layer INS5 is located. For example, the second transparent conductive layer TCL2 of the pad electrode LDP may be in contact with the first transparent conductive layer TCL1 through the first hole H1 that penetrates the fifth insulating layer INS5 to expose a part of the first transparent conductive layer TCL1.

The second transparent conductive layer TCL2 may include a conductive material suitable for improving adhesion and/or contact resistance. For example, the second transparent conductive layer TCL2 may include a transparent conductive oxide including or containing at least one element among the elements that consists of the conductive material of the first transparent conductive layer TCL1.

According to the embodiment, the first transparent conductive layer TCL1 and the second transparent conductive layer TCL2 may include a transparent conductive oxide including or containing indium (In). For example, the first transparent conductive layer TCL1 may be made of indium-tin oxide (ITO), indium-zinc oxide (IZO), or indium-gallium-zinc oxide (IGZO), and the second transparent conductive layer TCL2 may be made of indium-tin oxide (ITO). Accordingly, the contact resistance between the first transparent conductive layer TCL1 and the second transparent conductive layer TCL2 can be lowered.

As the contact resistance between the first transparent conductive layer TCL1 and the second transparent conductive layer TCL2 is lowered, it is possible to prevent or reduce the voltage drop in the pixel voltage supplied to the common electrode CE through the voltage line VSL. For example, the voltage drop effect of the pixel voltage can be further increased by connecting the low-resistance voltage line VSL with the common electrode CE through the pad electrode LDP.

The second metal layer MTL2 may include a metal with high reflectance. For example, the second metal layer MTL2 may include a metal such as silver (Ag), molybdenum (Mo), titanium (Ti), copper (Cu) and aluminum (Al). According to an embodiment, the second metal layer MTL2 may be made up of, but is not limited to, a single metal layer including or containing silver (Ag).

The third transparent conductive layer TCL3 may include a conductive material suitable for improving adhesion and/or contact resistance. The third transparent conductive layer TCL3 may include a conductive material suitable for optical properties (for example, resonance structure) required by the pixel electrode AE that is disposed in the emission area EA of each pixel PX and has the same material and/or cross-sectional structure as the pad electrode LDP. As an example, the third transparent conductive layer TCL3 may include transparent conductive oxide.

According to the embodiment, the second transparent conductive layer TCL2 and the third transparent conductive layer TCL3 may be formed of the same conductive material, thereby increasing the fabrication efficiency. For example, the second transparent conductive layer TCL2 and the third transparent conductive layer TCL3 may be made of indium-tin oxide (ITO). According to an embodiment where the second metal layer MTL2 is made of a single metal layer including or containing silver (Ag), each of the pixel electrode AE located in the emission area EA and the pad electrode LDP located in the non-emission area NEA may have a triple-layer structure of ITO/Ag/ITO.

The common electrode CE may be disposed on an insulating layer over the pad electrode LDP, for example, the pixel-defining layer PDL. The common electrode CE may be in contact with the pad electrode LDP where the second hole H2 of the pixel-defining layer PDL is located. For example, the common electrode CE may be in contact with the third transparent conductive layer TCL3 of the pad electrode through the second hole H2 that penetrates the pixel-defining layer PDL to expose a part of the pad electrode LDP, for example, a part of the third transparent conductive layer TCL3.

The common electrode CE may be connected to the voltage line VSL by the pad electrode LDP. According to an embodiment, the display panel 110 may be a top-emission display panel, and the common electrode CE may be made of a transparent conductive material that can transmit light (for example, a transparent conductive oxide), or a translucent conductive material such as magnesium (Mg) and silver (Ag) or an alloy of magnesium (Mg) and silver (Ag) (for example, a translucent metallic material).

According to an embodiment, the light-emitting element EL may include at least one common layer CML (for example, a first common layer CML1 and a second common layer CML2) disposed between the pixel electrode AE and the common electrode CE in FIG. 4 and formed entirely in the display area DA, and the common layer CML may be disposed between the pixel-defining layer PDL and the common electrode CE in the non-emission area NEA. In this instance, the second hole H2 may penetrate the common layer CML and the pixel-defining layer PDL.

FIG. 6 is a schematic cross-sectional view showing a display panel 110 according to an embodiment. For example, FIG. 6 is a schematic cross-sectional view showing a portion of the display area DA of the display panel 110, which does not include the bridge electrode BRE or the fifth insulating layer INS5 of FIG. 4. In the following description on the embodiment of FIG. 6, the redundant descriptions of similar or identical elements with those of the embodiment of FIGS. 4 and 5 will be omitted.

Referring to FIG. 6 in conjunction with FIGS. 1 to 5, the panel circuit layer PCL may not include the bridge electrode BRE and the fifth insulating layer INS5, and the light-emitting element layer LEL may be disposed on the fourth insulating layer INS4. For example, the pixel electrode AE may be disposed on the fourth insulating layer INS4 and may be connected directly to one electrode (for example, the source electrode SE) of the transistors TR through at least one via hole VH penetrating the fourth insulating layer INS4.

The pad electrode LDP may be disposed on the fourth insulating layer INS4 together with the pixel electrode AE. For example, the pad electrode LDP may be disposed on the fourth insulating layer INS4 and may be connected to the voltage line VSL through the first hole H1 penetrating the fourth insulating layer INS4.

The voltage line VSL may be disposed on the third insulating layer INS3. For example, the voltage line VSL may be disposed on the third insulating layer INS3 together with the source electrode SE and/or the drain electrode DE of the transistor TR.

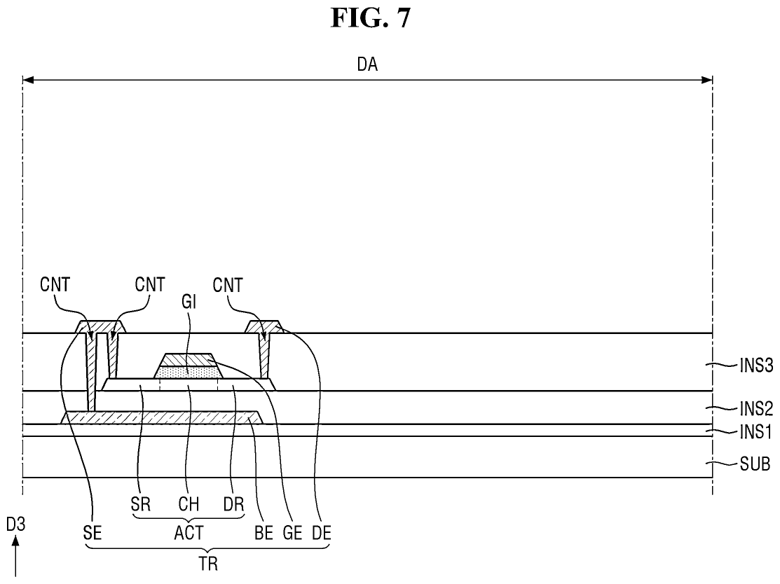

FIGS. 7 to 18 are schematic cross-sectional views illustrating a method of fabricating a display device 100 according to an embodiment. For example, FIGS. 7 to 18 sequentially show steps for fabricating the display panel 110 of FIG. 4.

Referring to FIG. 7 in conjunction with FIGS. 1 to 6, a substrate SUB including at least a display area DA may be prepared. The display area DA may include an emission area EA of each pixel PX and a non-emission area NEA around the emission area EA.

Subsequently, a transistor TR and first, second and third insulating layers INS1, INS2 and INS3 may be formed on the substrate SUB. For example, a first insulating layer INS1, a bottom electrode BE, a second insulating layer INS2, and an active layer ACT may be sequentially formed on the substrate SUB. Subsequently, a gate insulator GI and a gate electrode GE may be formed on the active layer ACT. According to the embodiment, an insulating film for forming a gate insulator GI and a conductive film for forming a gate electrode GE are sequentially formed on the second insulating layer INS2 where the active layer ACT is formed, and the conductive film and the insulating film are sequentially and/or continuously etched, so that the gate electrode GE and the gate insulator GI may be formed sequentially and/or continuously. Subsequently, a third insulating layer INS3 may be formed on the second insulating layer INS2 to cover the active layer ACT, the gate insulator GI and the gate electrode GE, and contact holes CNT (for example, contact holes CNT exposing the bottom electrode BE, the source region SR of the active layer ACT and the drain region DR of the active layer ACT, respectively) may be formed in the third insulating layer INS3. Subsequently, a source electrode SE and/or a drain electrode DE may be formed on the third insulating layer INS3. In this manner, the transistor TR can be formed on the substrate SUB.

As in the embodiment of FIG. 6 where the display panel 110 may include the voltage line VSL disposed on the third insulating layer INS3, the voltage line VSL may be formed on the third insulating layer INS3. For example, the source electrode SE and/or drain electrode DE and the voltage line VSL can be formed simultaneously.

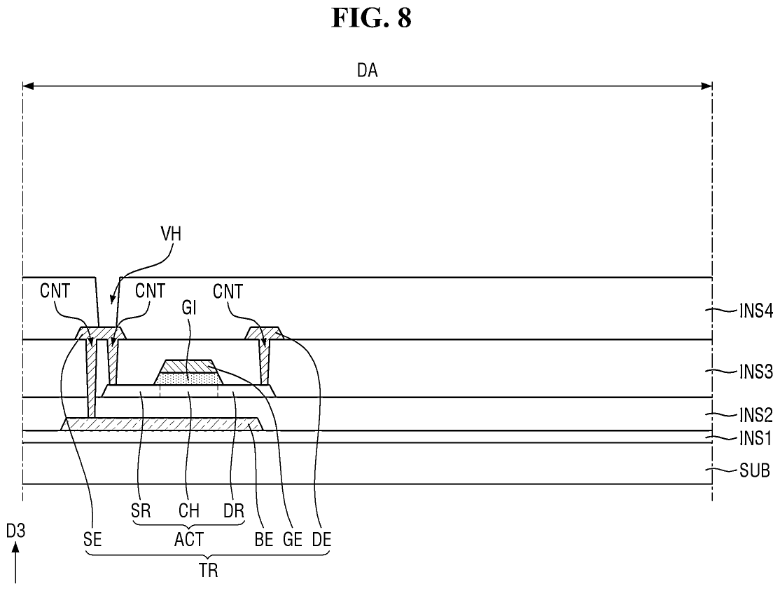

Referring to FIG. 8 in conjunction with FIGS. 1 to 7, a fourth insulating layer INS4 may be formed on the third insulating layer INS3, and at least one via hole VH penetrating the fourth insulating layer INS4 may be formed. The fourth insulating layer INS4 may be formed to cover the patterns of the conductive layer provided with the source electrode SE and/or the drain electrode DE.

For example, the fourth insulating layer INS4 may be formed on the third insulating layer INS3 to cover the source electrode SE and/or the drain electrode DE, and at least one via hole VH penetrating the fourth insulating layer INS4 (for example, a via hole VH exposing the source electrode SE) may be formed. As in the embodiment of FIG. 6 where the display panel 110 including the voltage line VSL disposed on the third insulating layer INS3 is fabricated, a first hole H1 that exposes the voltage line VSL may be further formed in the fourth insulating layer INS4.

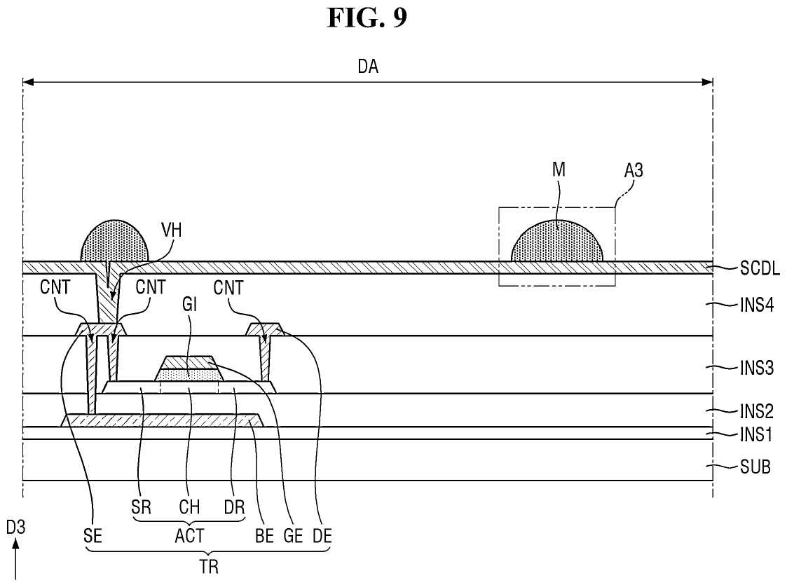

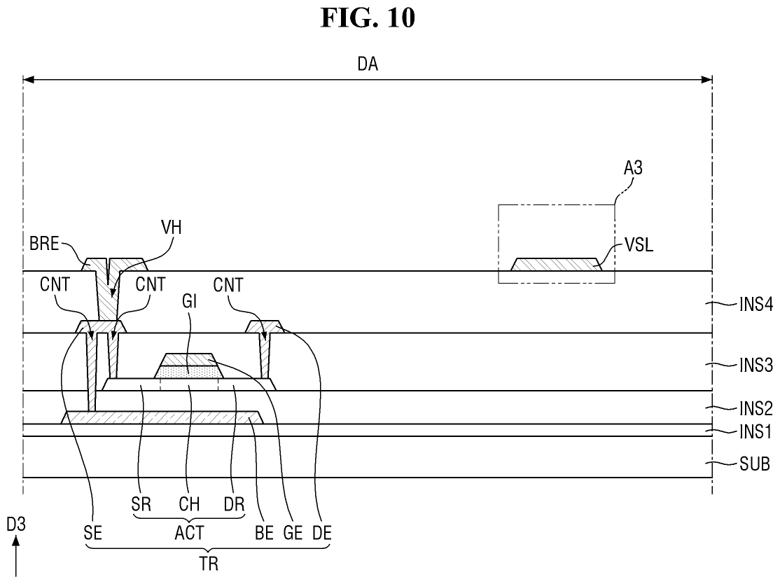

Referring to FIGS. 9 and 10 in conjunction with FIGS. 1 to 8, a bridge electrode BRE and a voltage line VSL may be formed on the fourth insulating layer INS4. For example, as shown in FIG. 9, a conductive film SCDL may be formed on the fourth insulating layer INS4, and the conductive film SCDL may be patterned via an etching process using a mask M to form the bridge electrode BRE and the voltage line VSL.

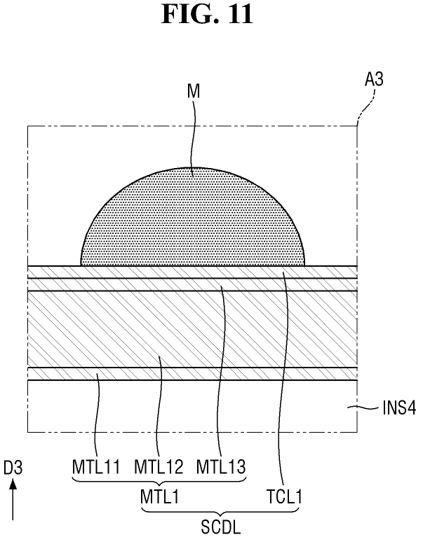

FIGS. 11 to 14 show an example of a method of forming a voltage line VSL in area A3 of FIGS. 9 and 10. The bridge electrode BRE may be formed together with the voltage line VSL during the processes of forming etching the conductive layer SCDL for forming the voltage line VSL. Hereinafter, a method of forming the bridge electrode BRE and the voltage line VSL will be described in more detail with reference to FIGS. 11 to 14 in conjunction with FIGS. 1 to 10.

Firstly, a multi-layer conductive film SCDL may be formed on the substrate SUB on which the fourth insulating layer INS4, etc. is formed, as shown in FIGS. 9 and 11. The conductive film SCDL may be formed entirely on the display area DA or the like within the spirit and the scope of the disclosure.

For example, by sequentially forming a first metal layer MTL1 and a first transparent conductive layer TCL1 on the fourth insulating layer INS4, a multi-layer conductive film SCDL including the first metal layer MTL1 and the first transparent conductive layer TCL1 on the first metal layer MTL1 may be formed. According to the embodiment, a first layer MTL11 including or containing a first metal, a second layer MTL12 including or containing a second metal, and a third layer MTL13 including or containing a third metal are formed sequentially on the fourth insulating layer INS4, so that a multi-layer first metal layer MTL1 including the first layer MTL11, the second layer MTL12 on the first layer MTL11 and the third layer MTL13 on the second layer MTL12 may be formed.

The first metal layer MTL1 may be formed using the above-listed conductive materials, for example, the first metal, the second metal and the third metal. The first transparent conductive layer TCL1 may be formed of a transparent conductive oxide including or containing the above-listed conductive materials, for example, indium (In).

Subsequently, a mask M may be placed on a portion of the conductive film SCDL. The mask M may be disposed on the conductive layer SCDL based on the pattern shape, size, and/or position of the bridge electrode BRE and the voltage line VSL to be formed in the display panel 110.

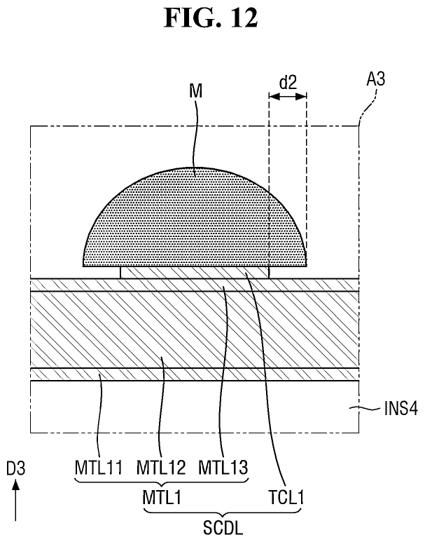

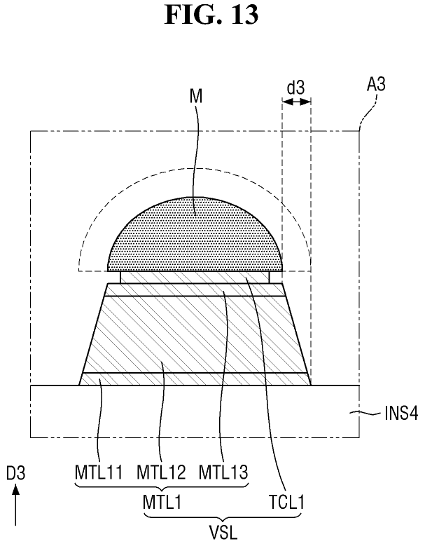

Subsequently, as shown in FIGS. 12 and 13, the voltage line VSL can be formed by sequentially etching the first transparent conductive layer TCL1 and the first metal layer MTL1 using the mask M. By sequentially etching the first transparent conductive layer TCL1 and the first metal layer MTL1, the bridge electrode BRE can be formed simultaneously with the voltage line VSL.

According to the embodiments, as shown in FIG. 12, the first transparent conductive layer TCL1 may be overly etched so that the first transparent conductive layer TCL1 has a width smaller than the mask M. For example, the first transparent conductive layer TCL1 may be etched into a pattern that has a width smaller than that of the mask M and is completely hidden by the mask M.

According to an embodiment, the first transparent conductive layer TCL1 may be overetched more than the amount of reduction of the mask M occurring in the process of etching the first transparent conductive layer TCL1 and the first metal layer MTL1 (for example, the amount of area reduction of the mask M due to consumption or wear of the mask M). For example, the first transparent conductive layer TCL1 may be overetched so that it has a smaller size than the size of the mask M considering the expected reduction of the mask M (for example, a width and/or area smaller than the mask M).

According to an embodiment, the first transparent conductive layer TCL1 may be etched via a wet etching process using the mask M. Accordingly, the first transparent conductive layer TCL1 can be isotropically overetched so that the first transparent conductive layer TCL1 has a smaller border than that of the mask M and is located on the inner side of the mask M. For example, the border of the first transparent conductive layer TCL1 may be located on the inner side of the border of the mask M, and the ends of the first transparent conductive layer TCL1 may be spaced apart from the ends of the mask M.

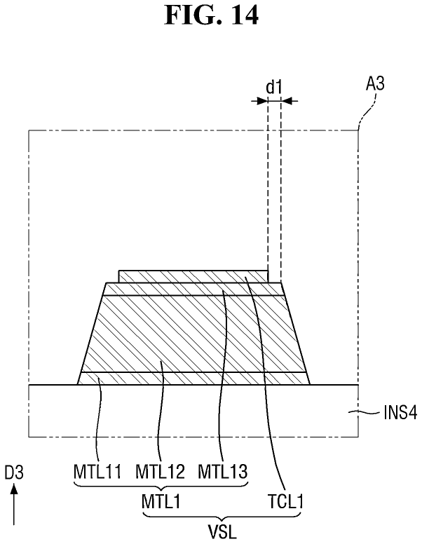

For example, the end of the first transparent conductive layer TCL1 of the voltage line VSL may be spaced apart from the end of the mask M by a second distance d2 that is equal to the sum of the distance corresponding to the amount of one-side reduction (or amount of retraction) of the mask M (for example, a third distance d3 in FIG. 13) and a first distance d1 corresponding to the process margin (for example, the first distance d1 in FIGS. 5 and 14) in the width direction. According to the embodiment, the first distance d1 may be equal to or greater than about 0.1 μm. The first transparent conductive layer TCL1 may be etched to have a one-side skewed amount of about 0.1 μm or more than the amount one-side reduction of the mask M.

According to an embodiment, the degree of etching the first transparent conductive layer TCL1 may be adjusted by adjusting at least one of the thickness and the etching time of the first transparent conductive layer TCL1. As an example, the first transparent conductive layer TCL1 may be overetched by increasing at least one of the thickness and the etching time of the first transparent conductive layer TCL1 so that the first transparent conductive layer TCL1 has a smaller width and/or area than the mask M. It should be noted that if the thickness of the first transparent conductive layer TCL1 is thin, the amount of overetching the first transparent conductive layer TCL1 may be limited even though the etching time is increased.

According to an embodiment, the first transparent conductive layer TCL1 may be formed using the same material as that of the second transparent conductive layer TCL2. For example, the first transparent conductive layer TCL1 may be formed of indium-tin oxide (ITO). Accordingly, the contact resistance between the first transparent conductive layer TCL1 and the second transparent conductive layer TCL2 can be lowered and/or minimized.

According to an embodiment, the first transparent conductive layer TCL1 may be formed using a material that has a work function similar to that of the second transparent conductive layer TCL2 and is different from the material of the second transparent conductive layer TCL2 (for example, a heterogeneous material including or containing at least one element included in the material of the second transparent conductive layer TCL2). For example, the first transparent conductive layer TCL1 may be formed of indium-zinc oxide (IZO) or indium-gallium-zinc oxide (IGZO). In this manner, it is possible to overly etch the first transparent conductive layer TCL1 readily to the target size while reducing and/or minimizing the contact resistance between the first transparent conductive layer TCL1 and the second transparent conductive layer TCL2. For example, for indium-tin oxide (ITO), a film is formed to have a given thickness (for example, about 150 Å) or more, crystallization occurs and accordingly the wet etch rate decreases rapidly. On the other hand, for indium-zinc oxide (IZO) and indium-gallium-zinc oxide (IGZO), a film is formed to have even a larger than, the wet etch rate may not significantly decrease. Therefore, the first transparent conductive layer TCL1 can be formed to have an appropriate or sufficient thickness, and the first transparent conductive layer TCL1 can be overetched properly and/or readily as desired. Compared to indium-tin oxide (ITO), indium-zinc oxide (IZO) and indium-gallium-zinc oxide (IGZO) may be a material with strong etching resistance to an etching gas (for example, chlorine gas) used to etch the first metal layer MTL1. Accordingly, in case that the first transparent conductive layer TCL1 is formed of indium-zinc oxide (IZO) or indium-gallium-zinc oxide (IGZO), it is possible to effectively suppress by-products during the etching process of the first metal layer MTL1. The work function of indium-zinc oxide (IZO) (for example, about 5.0 eV) and the work function of indium-gallium-zinc oxide (IGZO) (for example, about 4.5 eV) may have a value similar to the work function of indium-tin oxide (ITO) (for example, about 4.7 eV). Accordingly, even though the first transparent conductive layer TCL1 is formed of indium-zinc oxide (IZO) or indium-gallium-zinc oxide (IGZO), it is possible to reduce the contact resistance between the voltage line VSL and the pad electrode LDP. For example, in case that the first transparent conductive layer TCL1 and the second transparent conductive layer TCL2 are formed of indium-tin oxide (ITO), the contact resistance between the voltage line VSL and the pad electrode LDP can be greatly reduced to about 1Ω or less. Even in case that the first transparent conductive layer TCL1 is formed of indium-tin oxide (ITO) and the second transparent conductive layer TCL2 is formed of indium-zinc oxide (IZO) or indium-gallium-zinc oxide (IGZO), the contact resistance can be reduced by up to about 80% of the reduction in the contact resistance that can be obtained in case that the first transparent conductive layer TCL1 and the second transparent conductive layer TCL2 are formed of indium-tin oxide (ITO).

After etching the first transparent conductive layer TCL1, the first metal layer MTL1 may be etched using the mask M without removing the mask M. Accordingly, the voltage line VSL can be formed as shown in FIG. 13.

According to an embodiment, the first metal layer MTL1 may be etched by a dry etching process using the mask M. During the process of etching the first metal layer MTL1, the mask M may be consumed or worn out and thus may become smaller.

According to the embodiment, the first metal layer MTL1 may be formed to have a relatively small size in the upper layer. For example, the lower layer of the first metal layer MTL1 (for example, the first layer MTL11) may have a size equal to the size (for example, the width and/or area) of the mask M at the time of starting to etch the first metal layer MTL1. The upper layer of the first metal layer MTL1 (for example, the third layer MTL13) may have a size equal to the size of the mask M at the time of end of etching the first metal layer MTL1. For example, in the width direction of the first metal layer MTL1, the end of the first layer MTL11 may be spaced apart from the end of the third layer MTL13 by the third distance d3 at the end of the first metal layer MTL1.

Once the etching process of the conductive film SCDL to form the voltage line VSL, etc. (for example, the etching process for the first transparent conductive layer TCL1 and the first metal layer MTL1) is completed, the mask M may be removed as shown in FIG. 14. As an example, the mask M may be removed via a strip process.

According to the embodiments, the first transparent conductive layer TCL1 is overetched by the process margin equal to the first distance d1 more than the amount of reduction of the mask M on one side or a side at one end or an end, the first transparent conductive layer TCL1 can be stably covered by the mask M in the form of an undercut under or below the mask M until the etching process for the first metal layer MTL1 is completed. In this manner, while the etching process for the first metal layer MTL1 is in progress, it is possible to prevent or suppress the first transparent conductive layer TCL1 from being exposed to the etching gas and/or plasma. As a result, it is possible to prevent by-products from being generated due to additional etching of the first transparent conductive layer TCL1 during the etching process for the first metal layer MTL1, etc., and to prevent chamber contamination and defects in the display panel 110 resulted therefrom.

Accordingly, with respect to the contact surface between the first metal layer MTL1 and the first transparent conductive layer TCL1, the end of the first transparent conductive layer TCL1 may be spaced apart from the end of the first metal layer MTL1 (for example, the end of the third layer MTL13) by the first distance d1.

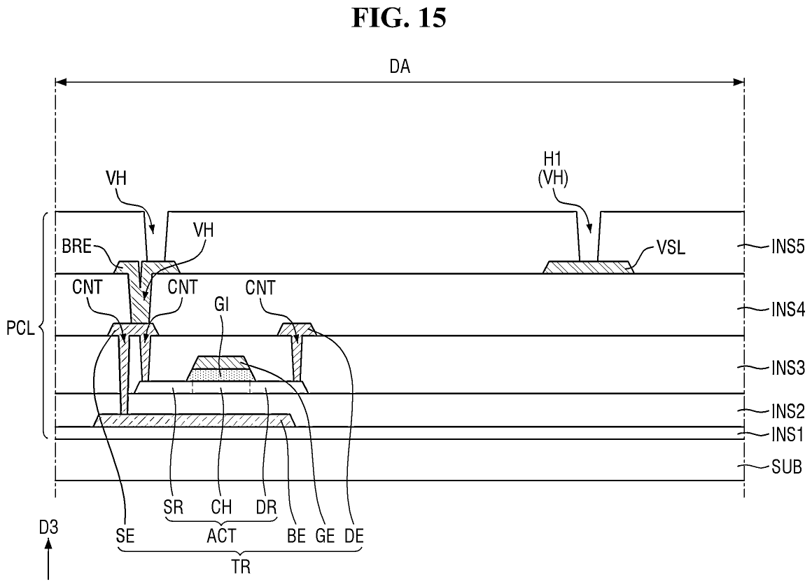

Referring to FIG. 15 in conjunction with FIGS. 1 to 14, a fifth insulating layer INS5 may be formed on the fourth insulating layer INS4, and at least one via hole VH penetrating the fifth insulating layer INS5 may be formed. The fifth insulating layer INS5 may be formed to cover the patterns of the conductive layer provided with the bridge electrode BRE and/or the voltage line VSL. Accordingly, a panel circuit layer PCL may be formed on the substrate SUB.

For example, the fifth insulating layer INS5 may be formed on the fourth insulating layer INS4 to cover the bridge electrode BRE and the voltage line VSL, etc., and at least one via hole VH may be formed through the fifth insulating layer INS5. As an example, a via hole VH exposing a part of the bridge electrode BRE and a first hole H1 exposing a part of the voltage line VSL may be formed in the fifth insulating layer INS5. As the first transparent conductive layer TCL1 is disposed at the top of the voltage line VSL, a part of the first transparent conductive layer TCL1 may be exposed where the first hole H1 is formed.

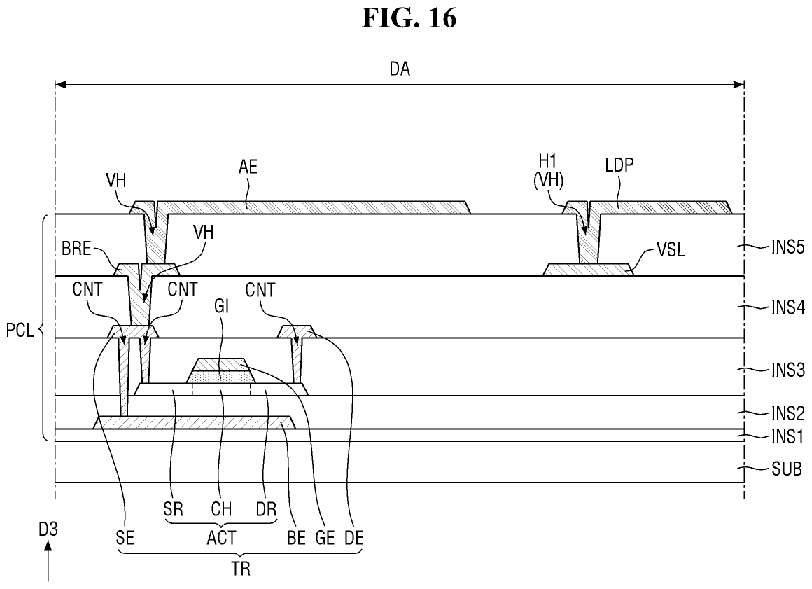

Referring to FIG. 16 in conjunction with FIGS. 1 to 15, a pixel electrode AE and a pad electrode LDP may be formed on the panel circuit layer PCL. For example, the pixel electrode AE and the pad electrode LDP may be formed on the fifth insulating layer INS5 via a film forming process and an etching process of the conductive film for forming the pixel electrode AE and the pad electrode LDP (for example, a multi-layer conductive film including the second transparent conductive layer TCL2, the second metal layer MTL2 on the second transparent conductive layer TCL2, and the third transparent conductive layer TCL3 on the second metal layer MTL2 in FIG. 4).

The pixel electrode AE may overlap the bridge electrode BRE and may be connected to the bridge electrode BRE through a via hole VH formed on the bridge electrode BRE.

The pad electrode LDP may overlap the voltage line VSL and may be connected to the voltage line VSL through a first hole H1 formed on the voltage line VSL. For example, the pad electrode LDP may be in contact with the first transparent conductive layer TCL1 of the voltage line VSL where the first hole H1 is located.

According to the embodiments, the pad electrode LDP may include a second transparent conductive layer TCL2 in contact with the first transparent conductive layer TCL1 of the voltage line VSL. The first transparent conductive layer TCL1 and the second transparent conductive layer TCL2 may be formed of a transparent conductive oxide including or containing one or more same elements. For example, the first transparent conductive layer TCL1 and the second transparent conductive layer TCL2 may be formed of a transparent conductive oxide including or containing indium (In). According to an embodiment, the first transparent conductive layer TCL1 may be formed of indium-tin oxide (ITO), indium-zinc oxide (IZO), or indium-gallium-zinc oxide (IGZO), and the second transparent conductive layer TCL2 may be formed of indium-tin oxide (ITO).

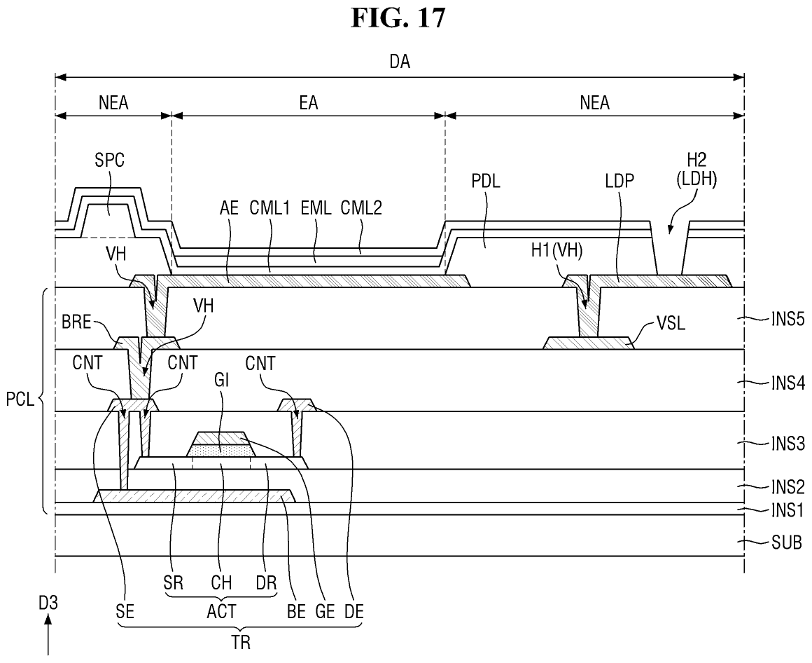

Referring to FIG. 17 in conjunction with FIGS. 1 to 16, a pixel-defining layer PDL may be formed over the panel circuit layer PCL, the pixel electrode AE and the pad electrode LDP. The pixel-defining layer PDL may have an opening the emission area EA and may expose the pixel electrode AE in the emission areas EA. According to the embodiment, the pixel-defining layer PDL and the spacer SPC may be formed simultaneously using a halftone mask, etc., but the disclosure is not limited thereto. After forming the pixel-defining layer PDL, an emissive layer EML may be formed on the pixel electrode AE. According to the embodiment, the emissive layer EML may be formed at least in the emission area EA. According to the embodiment, at least one common layer CML may be formed before and after forming the emissive layer EML. For example, after forming the pixel-defining layer PDL, a first common layer CML1, an emissive layer EML and a second common layer CML2 may be sequentially formed on the pixel electrode AE.

According to the embodiment, a second hole H2 may be formed in the pixel-defining layer PDL to expose a part of the pad electrode LDP. According to the embodiment, the second hole H2 may be formed by laser drilling. For example, the second hole H2 may be formed in the pixel-defining layer PDL by removing an organic film including the pixel-defining layer PDL on a portion of the pad electrode LDP using a laser. The second hole H2 may be formed before or after the emissive layer EML has been formed. As an example, the second hole H2 may be formed after the second common layer CML2 has been formed and may penetrate the pixel-defining layer PDL, the first common layer CML1 and the second common layer CML2.

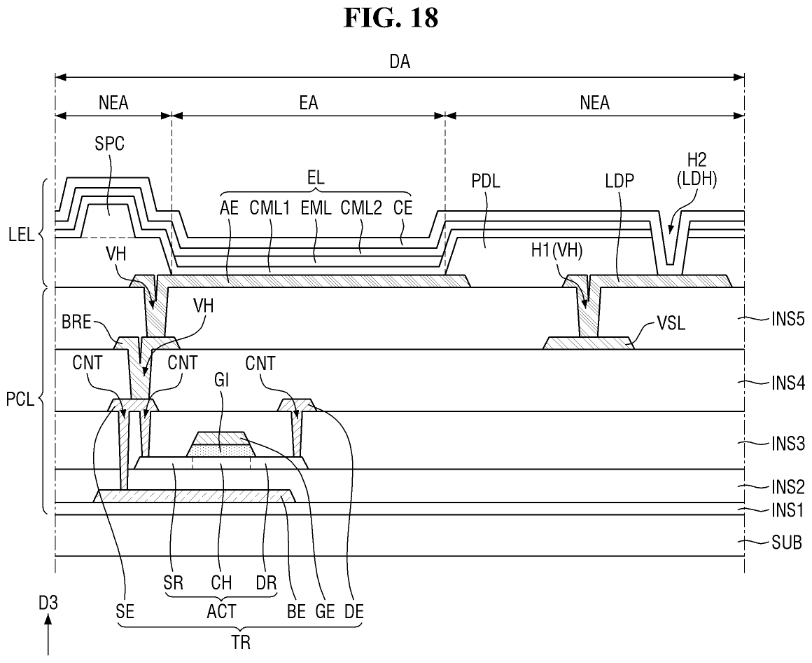

Referring to FIG. 18 in conjunction with FIGS. 1 to 17, a common electrode CE may be formed on the pixel-defining layer PDL and the emissive layer EML. In this manner, the light-emitting element layer LEL can be formed on the panel circuit layer PCL.

The common electrode CE may overlap the pixel electrode AE and the emissive layer EML in the emitting area EA and may overlap the pad electrode LDP in the non-emission area NEA. The common electrode CE may be in contact with the pad electrode LDP where the second hole H2 is located.

In case that the display panel 110 may include the encapsulation layer ENL shown in FIG. 4 or the like, an encapsulation layer ENL may be formed on the light-emitting element layer LEL. In this manner, the display panel 110 can be fabricated.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A display device comprising:
a voltage line disposed in a display area on a substrate, the voltage line comprising a first metal layer and a first transparent conductive layer on the first metal layer;
an insulating layer disposed on the voltage line, the insulating layer comprising a first hole exposing a part of the first transparent conductive layer;
a pad electrode disposed on the insulating layer, the pad electrode comprising a second transparent conductive layer contacting the first transparent conductive layer where the first hole of the insulating layer is disposed;
a pixel-defining layer disposed on the pad electrode, the pixel-defining layer comprising a second hole exposing a part of the pad electrode; and
a common electrode disposed on the pixel-defining layer and contacting the pad electrode where the second hole is disposed, wherein
the first transparent conductive layer has a smaller width than a width of the first metal layer, and
an end of the first transparent conductive layer is spaced apart from an end of the first metal layer by a first distance at an end of the voltage line.

2. The display device of claim 1, wherein the first distance is equal to or greater than about 0.1 μm.

3. The display device of claim 2, wherein the first distance is in a range of about 0.1 μm to about 0.2 μm.

4. The display device of claim 1, wherein the first transparent conductive layer and the second transparent conductive layer comprise one or more same elements.

5. The display device of claim 4, wherein the first transparent conductive layer and the second transparent conductive layer comprise a transparent conductive oxide including indium (In).

6. The display device of claim 5, wherein
the first transparent conductive layer is made of indium-tin oxide (ITO), indium-zinc oxide (IZO), or indium-gallium-zinc oxide (IGZO), and
the second transparent conductive layer is made of indium-tin oxide (ITO).

7. The display device of claim 1, wherein the first metal layer protrudes from both sides of the first transparent conductive layer in a width direction of the voltage line.

8. The display device of claim 1, wherein the first metal layer has a multi-layer structure comprising:
a first layer including a first metal;
a second layer disposed on the first layer and including a second metal; and
a third layer disposed on the second layer and including a third metal.

9. The display device of claim 8, wherein
the first metal and the third metal are titanium (Ti), and
the second metal is aluminum (Al).

10. The display device of claim 1, wherein the pad electrode further comprises:
a second metal layer disposed on the second transparent conductive layer; and
a third transparent conductive layer disposed on the second metal layer.

11. The display device of claim 10, wherein
the second transparent conductive layer and the third transparent conductive layer include indium-tin oxide (ITO), and
the second metal layer includes silver (Ag).

12. The display device of claim 1, further comprising:
a panel circuit layer disposed on the substrate and comprising a transistor disposed in the display area and the voltage line;
a light-emitting element layer disposed in the display area on the panel circuit layer and comprising:
a pixel electrode disposed in a same layer as the pad electrode and spaced apart from the pad electrode;
an emissive layer disposed between the pixel electrode and the common electrode;
the common electrode; and
the pixel-defining layer; and
an encapsulation layer disposed on the light-emitting element layer.

13. The display device of claim 12, wherein the pixel-defining layer is opened in an emission area where the pixel electrode and the emissive layer overlap each other to expose the pixel electrode.

14. The display device of claim 13, wherein
the display area further comprises a non-emission area around the emission area,
the common electrode is disposed entirely in the display area, and
the pad electrode and the second hole are disposed in the non-emission area.

15. The display device of claim 14, further comprising:
at least one common layer disposed between the pixel-defining layer and the common electrode and overlapping the pad electrode,
wherein the second hole penetrates the pixel-defining layer and the at least one common layer.

16. A method of fabricating a display device, the method comprising:
forming a multi-layer conductive film by sequentially forming a first metal layer and a first transparent conductive layer on a substrate;
disposing a mask on a portion of the conductive film;
forming a voltage line by sequentially etching the first transparent conductive layer and the first metal layer using the mask;
forming an insulating layer on the voltage line and forming a first hole in the insulating layer to expose a portion of the first transparent conductive layer;
forming a pad electrode on the insulating layer, the pad electrode overlapping the voltage line and contacting the first transparent conductive layer where the first hole is disposed;
forming a pixel-defining layer and at least one common layer over the pad electrode, and forming a second hole in the pixel-defining layer and the at least one common layer to expose a portion of the pad electrode; and
forming a common electrode on the pixel-defining layer, the common electrode overlapping the pad electrode and contacting the pad electrode where the second hole is disposed,
wherein the etching of the first transparent conductive layer comprises overly etching the first transparent conductive layer by more than an amount of reduction of the mask that occurs in the process of etching the first transparent conductive layer and the first metal layer.

17. The method of claim 16, wherein the first transparent conductive layer is etched into a pattern that has a width smaller than a width of the mask and having an upper surface completely covered by the mask.

18. The method of claim 16, wherein the first transparent conductive layer is etched to have a one-side skewed amount of about 0.1 μm or more than the one-side reduction amount of the mask.

19. The method of claim 16, wherein
the pad electrode comprises a second transparent conductive layer contacting the first transparent conductive layer, and
the first transparent conductive layer and the second transparent conductive layer are formed of a transparent conductive oxide including one or more same elements.

20. The method of claim 19, wherein the first transparent conductive layer is made of indium-tin oxide (ITO), indium-zinc oxide (IZO), or indium-gallium-zinc oxide (IGZO), and the second transparent conductive layer is made of indium-tin oxide (ITO).
